(19) United States
(12) Patent Application Publication
(10) Pub. No.: US 2026/0328874 A1
(43) Pub. Date: Oct. 22, 2026

(54) OPTICALLY PUMPED MAGNETOMETER AND MAGNETIC MEASUREMENT METHOD

(71) Applicant: SHIMADZU CORPORATION, Kyoto-shi (JP)

(72) Inventors: Naoki UMETANI, Kyoto-shi (JP); Tetsuo KOBAYASHI, Kyoto-shi (JP)

(21) Appl. No.: 19/652,718

(22) Filed: Apr. 20, 2026

(30) Foreign Application Priority Data
Apr. 18, 2025 (JP) 2025-068516

(51) Int. Cl. G01R 33/26

(52) U.S. Cl. CPC G01R 33/26

(57) ABSTRACT

An optically pumped magnetometer in the present disclosure includes a cell, a laser irradiation unit, a magnetic field generation unit, a detector, and a control device. Helium is enclosed in the cell. The laser irradiation unit irradiates the cell with first laser light. The magnetic field generation unit applies a static magnetic field to the cell in a direction intersecting the first laser light. The detector detects the first laser light that has passed through the cell. The control device controls the magnetic field generation unit and measures a periodic magnetic field acting on the cell based on a detection result of the detector.

### TECHNICAL FIELD

The present disclosure relates to an optically pumped magnetometer and a magnetic measurement method, and more specifically, to a technique for improving measurement sensitivity to a periodic magnetic field.

### BACKGROUND ART

As a sensor capable of measuring a weak magnetic field, an optically pumped magnetometer (hereinafter also referred to as "OPM") is known. By irradiating gaseous atoms (excited species) enclosed in a cell with left-circularly polarized or linearly polarized pump light, the atoms are brought into a specific excited state. When the excited atoms return to the ground state, the spins become polarized. For example, in an OPM using alkali metal atoms pumped with left-circularly polarized light, a state of spin polarization called "Orientation," which can be regarded as macroscopic magnetization, changes when it receives a magnetic field. In this type of OPM, a weak magnetic field can be measured by detecting a change in the direction of the main axis of spin polarization using probe light.

According to the OPM, it is also possible to measure the intensity of a periodic magnetic field in which the intensity of the magnetic field changes periodically. Here, a measurement signal output by the OPM by measuring the periodic magnetic field is affected by the frequency of the periodic magnetic field. For example, when two periodic magnetic fields having the same intensity but different frequencies are measured by the OPM, the output signal intensity differs for each magnetic field. Therefore, depending on the frequency of the periodic magnetic field, the intensity of the output measurement signal may become small, making it difficult to measure the intensity of the magnetic field. In this regard, Japanese Patent Application Laid-Open No. 2021-139709 (Patent Literature 1) discloses a technique for expanding the frequency band of a measurable periodic magnetic field by applying a static magnetic field to a cell of an OPM.

### Citation List

### Patent Literature

Patent Literature 1 Japanese Patent Application Laid-Open No. 2021-139709

### SUMMARY OF INVENTION

### Technical Problem

According to Patent Literature 1, the frequency band of a measurable periodic magnetic field can be expanded. However, in Patent Literature 1, the above-mentioned alkali metal atoms are used as the excited species of the OPM. Since the excited species need to be in a gaseous state, in an OPM using alkali metal atoms, it is necessary to heat the alkali metal to make it gaseous. Since the OPM may reach a high temperature due to heat generated by heating, it is necessary to arrange the OPM away from a measurement target. A magnetic field generated from a measurement target attenuates as the distance between the measurement target and the OPM increases. Therefore, there has been a concern about a decrease in sensitivity due to the OPM being arranged at a position that takes a relatively long distance from the measurement target.

The present disclosure was made to solve such a problem, and an object thereof is to improve measurement sensitivity to a periodic magnetic field in an OPM.

### SOLUTION TO PROBLEM

An optically pumped magnetometer in one aspect of the present disclosure includes a cell in which helium is enclosed, a laser irradiation unit that irradiates the cell with first laser light, a magnetic field generation unit that applies a static magnetic field to the cell in a direction intersecting the first laser light, a detector that detects the first laser light that has passed through the cell, and a control device that controls the magnetic field generation unit and measures a periodic magnetic field acting on the cell based on a detection result of the detector.

A magnetic measurement method in one aspect of the present disclosure includes: (1) a step of irradiating a cell in which helium is enclosed with laser light; (2) a step of applying a static magnetic field to the cell in a direction intersecting the laser light; (3) a step of detecting the laser light that has passed through the cell; and (4) a step of measuring a periodic magnetic field acting on the cell based on a detection result of the detector.

### ADVANTAGEOUS EFFECTS OF INVENTION

According to the present disclosure, it is possible to improve measurement sensitivity to a periodic magnetic field in an OPM.

### BRIEF DESCRIPTION OF DRAWINGS

FIG. 1 is a diagram schematically showing an overall configuration of an OPM in Embodiment 1.

FIG. 2 is a diagram schematically showing a measurement principle by the OPM in Embodiment 1.

FIG. 3 is a diagram schematically showing an overall configuration of an OPM in a comparative example.

FIG. 4 is a flowchart for explaining a magnetic measurement method in Embodiment 1.

FIG. 5 is a diagram showing an example of measurement results by the OPM in Embodiment 1.

FIG. 6 is a diagram showing an example of measurement results by the OPM when no static magnetic field is applied.

FIG. 7 is a diagram showing an example of measurement results by the OPM in Embodiment 1.

FIG. 8 is a diagram schematically showing an overall configuration of an OPM in Embodiment 2.

### DESCRIPTION OF EMBODIMENTS

Embodiments will be described in detail below with reference to the drawings. Note that in the following, the same or corresponding parts in the drawings are denoted by the same reference numerals, and description thereof will not be repeated.

### Embodiment 1

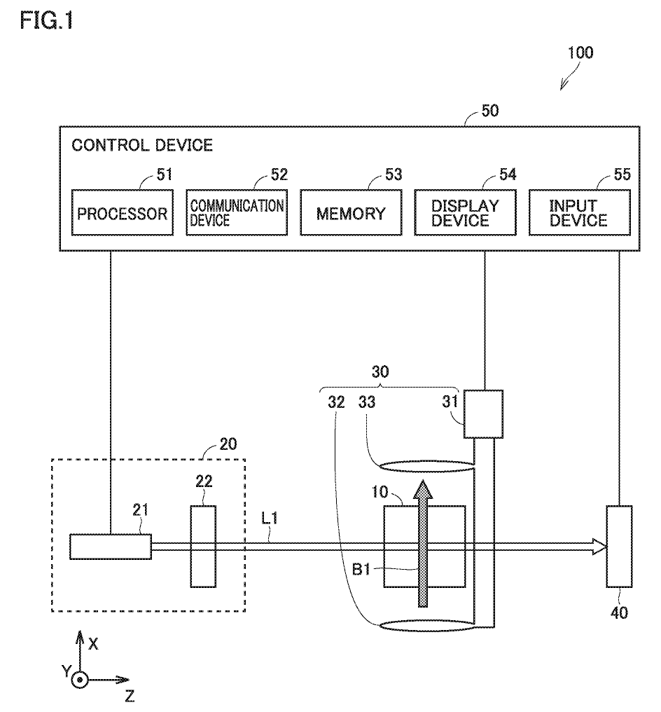

A configuration of an OPM 100 in Embodiment 1 will be described with reference to FIG. 1. FIG. 1 is a schematic diagram for explaining the configuration of the OPM 100 in Embodiment 1. The OPM 100 is capable of measuring a weak magnetic field. The weak magnetic fields are, for example, a magnetoencephalogram and a magnetocardiogram. The OPM 100 includes a glass cell 10, a laser irradiation unit 20, a magnetic field generation unit 30, a detector 40, and a control device 50.

Helium 4 (⁴He) (hereinafter referred to as helium) is enclosed inside the glass cell 10. Although not shown in FIG. 1, the glass cell 10 includes an electrode that performs discharge to generate a metastable state of internal helium.

The glass cell 10 is made of glass capable of transmitting light. Glass materials constituting the glass cell 10 are, for example, quartz, sapphire, silicon, Kovar glass, and borosilicate glass. The glass cell 10 is not limited to being composed of the above-mentioned materials, and may be composed of any material having light transparency to laser light L1.

The laser irradiation unit 20 is connected to the control device 50 and emits laser light in response to a command from the control device. The laser irradiation unit 20 includes a first light source 21 and a first polarizing element 22. Laser light L1 emitted by the first light source 21 is irradiated to the glass cell 10 after passing through the first polarizing element 22. The first polarizing element 22 includes an element that converts input light into a linearly polarized wave. Therefore, the laser light L1 that passes through the first polarizing element 22 and is irradiated to the glass cell 10 is a linearly polarized wave. The first polarizing element 22 is, for example, a 1/2 wavelength plate.

The wavelength of the laser light L1 emitted by the laser irradiation unit 20 is a resonance wavelength of helium in the glass cell 10 and is set to a wavelength at which a signal change due to spin polarization of helium is easily measured. Specifically, the laser light emitted by the laser irradiation unit 20 is, for example, laser light with a wavelength of 1083 nm. Thereby, helium can be efficiently excited by irradiating the glass cell 10 with the laser light L1. Furthermore, the detection intensity of the laser light L1 by the detector 40 is secured, making it easier to measure the signal change due to the spin polarization of helium.

In Embodiment 1, the laser light L1 emitted by the laser irradiation unit 20 is used as pump light for exciting helium and probe light for detecting the inclination of the spin polarization axis of helium.

The detector 40 is a polarimeter that detects the laser light L1 that has passed through the glass cell 10. The detector 40 is connected to the control device 50. A detection result by the detector 40 is transmitted to the control device 50 as an output signal.

The laser light L1 that has passed through the glass cell 10 includes information indicating the state of the excited helium atoms. The information indicating the state of the optically pumped helium atoms is, for example, information regarding spin polarization serving as a quadrupole moment called "alignment" of helium atoms.

The detector 40 is, for example, a differential detector. The detector 40 includes a polarization beam splitter (not shown), a first photodiode, a second photodiode, and a differential amplifier.

The polarization beam splitter outputs a first light component having a first polarization included in the laser light L1 to the first photodiode, and outputs a second light component having a polarization other than the first polarization to the second photodiode. The first polarization is, for example, the polarization of the laser light L1 before passing through the glass cell 10. The second light component is a light component generated by passing through the glass cell 10. In this case, the second light component includes information indicating the state of the optically pumped helium atoms.

The first photodiode inputs a signal corresponding to the intensity of the first light component to the differential amplifier, and the second photodiode inputs a signal corresponding to the intensity of the second light component to the differential amplifier. The differential amplifier generates a signal according to a difference between the signals received from the first photodiode and the second photodiode, and transmits the signal to the control device 50.

The magnetic field generation unit 30 is connected to the control device 50 and applies a static magnetic field (bias magnetic field) B1 to the glass cell 10 in response to a command from the control device 50. Note that although the intensity of the "static magnetic field" is constant without changing in a series of measurements, it is variable for each measurement.

The magnetic field generation unit 30 includes a power supply device 31 and a pair of coils 32, 33. The power supply device 31 supplies current to the pair of coils 32, 33 in response to a command from the control device 50. The control device 50 controls the magnitude of the current supplied from the power supply device 31 to the pair of coils 32, 33.

The pair of coils 32, 33 are arranged so as to sandwich the glass cell 10. The coils 32, 33 apply the static magnetic field B1 to the glass cell 10 by being supplied with current from the power supply device 31. The direction of the static magnetic field B1 is, for example, a direction from the coil 32 toward the coil 33 (positive direction along the X-axis) and is a direction intersecting the laser light L1.

The laser light L1 irradiated to the glass cell 10 and the static magnetic field B1 applied to the glass cell 10 by the magnetic field generation unit 30 are orthogonal to each other. Hereinafter, the traveling direction of the laser light L1 is also referred to as a Z-axis direction, the direction of the static magnetic field B1 applied by the magnetic field generation unit 30 is also referred to as an X-axis direction, and a direction orthogonal to the Z-axis and the X-axis is also referred to as a Y-axis direction.

The coils 32, 33 according to Embodiment 1 have a Helmholtz coil shape including a pair of coils respectively arranged at both ends of the glass cell 10 in the X-axis direction. Note that the coils 32, 33 are not necessarily limited to having a Helmholtz coil shape. The magnetic field generation unit 30 is not limited to a configuration having a Helmholtz coil shape as long as it can apply a static magnetic field to the glass cell 10 and the intensity of the static magnetic field can be switched, and may be a solenoid or a permanent magnet.

The control device 50 is, for example, a computer configured according to a general-purpose computer architecture. The control device 50 controls the operation of each part constituting the OPM 100 and measures a periodic magnetic field, which is a measurement target, based on a signal output from the detector 40. The control device 50 is configured according to a general-purpose computer architecture as an example. The control device 50 includes a processor 51, a communication device 52, a memory 53, a display device 54, and an input device 55.

The processor 51 is a calculation main body (computer) that executes various processes according to various programs. The processor 51 is composed of, for example, at least any one of a CPU (Central Processing Unit), an FPGA (Field Programmable Gate Array), a GPU (Graphics Processing Unit), and an MPU (Multi Processing Unit). Note that the processor 51 may be composed of processing circuitry.

The communication device 52 transmits and receives data among the laser irradiation unit 20, the magnetic field generation unit 30, and the detector 40 through a wired connection or a wireless connection.

The memory 53 is composed of a volatile memory such as a DRAM (Dynamic Random Access Memory) and an SRAM (Static Random Access Memory), or a non-volatile memory such as a ROM (Read Only Memory). The memory 53 stores various programs and data executed by the processor 51.

Note that the memory 53 may be a CD-ROM (Compact Disc-Read Only Memory), a DVD-ROM (Digital Versatile Disk-Read Only Memory), a USB (Universal Serial Bus) memory, a memory card, an FD (Flexible Disk), an HDD (Hard Disk Drive), an SSD (Solid State Drive), a magnetic tape, a cassette tape, an MO (Magnetic Optical Disc), an MD (Mini Disc), an IC (Integrated Circuit) card, an optical card, a mask ROM, or an EPROM, as long as programs and data can be non-temporarily recorded in a format readable by the control device 50.

The display device 54 includes a display such as a liquid crystal display, a plasma display, and an organic EL (Electro Luminescence) display, and displays predetermined information based on control of the processor 51.

The input device 55 is an input interface, such as a keyboard and a mouse, that accepts an input by a user. The user inputs, for example, the intensity of the static magnetic field B1 into the input device 55. The input device 55 outputs a signal based on the accepted user input to the processor 51. Note that the control device 50 may be provided with a touch panel in which the display device 54 and the input device 55 are integrated.

In the measurement of the OPM 100, the glass cell 10, the magnetic field generation unit 30, and the measurement target are surrounded by an electromagnetic shield and a magnetic shield (not shown). The electromagnetic shield shields high-frequency (for example, 10 kHz or higher) electromagnetic noise. The magnetic shield shields low-frequency (for example, 100 Hz or lower) magnetic noise. Since the electromagnetic shield and the magnetic shield surround the glass cell 10, the magnetic field generation unit 30, and the measurement target, the S/N ratio in the measurement of the periodic magnetic field derived from the measurement target can be improved.

### Measurement Principle

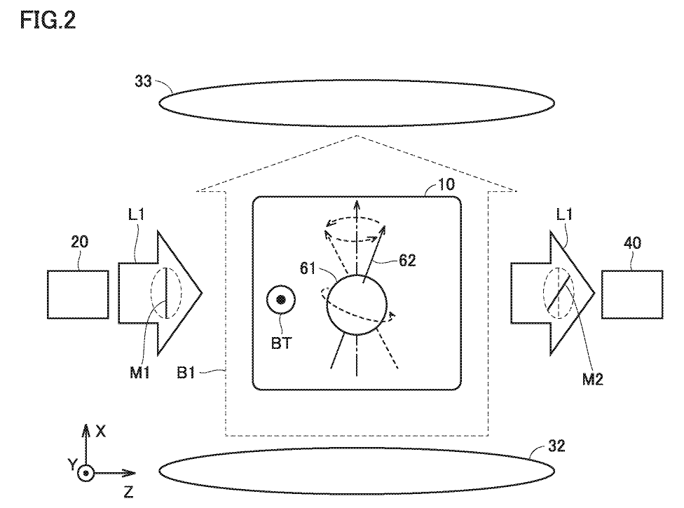

The principle of magnetic force measurement by the OPM 100 in the embodiment will be described. The OPM 100 in the embodiment measures a periodic magnetic field acting on the glass cell 10. FIG. 2 is a diagram schematically showing a principle by which the OPM 100 measures a magnetic field BT, which is a periodic magnetic field. Although FIG. 2 shows an example in which the magnetic field BT is a magnetic field vibrating along the Y-axis direction, the direction of the magnetic field to be measured is not limited to the Y-axis direction. Further, the periodic magnetic field is a magnetic field whose intensity changes at a predetermined frequency, and includes a radio frequency magnetic field (RF magnetic field). The 1periodic magnetic field is, for example, a magnetic field whose intensity changes in a sine curve shape.

First, by irradiating the glass cell 10 in which helium is enclosed with the laser light L1, a rotation axis 62 of helium atoms 61 in the glass cell 10 is brought into a state of facing a predetermined direction. Subsequently, in the OPM 100 in the embodiment, the magnetic field generation unit 30 applies the static magnetic field B1 to the glass cell 10. As a result, the helium atoms 61 in the glass cell 10 precess about the static magnetic field B1 as an axis. This precession is called Larmor precession.

The rotation frequency of the Larmor precession is called a Larmor frequency. The Larmor frequency has a value proportional to the magnitude of the static magnetic field B1. Therefore, if the Larmor frequency is determined, the magnitude of the static magnetic field B1 can be determined.

The polarization of the laser light L1 changes from polarization M1 to polarization M2 by passing through the glass cell 10. The change in polarization is affected by the Larmor frequency of the helium atoms 61 in the glass cell 10. Therefore, the magnitude of the magnetic field BT can be measured from the time change of the polarization detected by the detector 40. Specifically, the magnitude of the magnetic field BT is measured from the spectral density of the frequency of the signal detected by the detector 40.

When the frequency of the magnetic field BT matches the frequency of the Larmor precession, the response at that frequency increases due to a magnetic resonance phenomenon. Therefore, in the OPM 100, by adjusting the magnitude of the static magnetic field B1, it becomes possible to measure a periodic magnetic field of an arbitrary frequency with high sensitivity.

### Comparative Example

OPMs are known as sensors capable of measuring weak magnetic fields. Although a periodic magnetic field can also be measured according to the OPM, it is known that the measurement signal of the OPM is affected by the frequency of the periodic magnetic field. Therefore, depending on the frequency of the periodic magnetic field, the intensity of the output measurement signal becomes small and the S/N ratio becomes small, so it may be difficult to measure the intensity of the magnetic field.

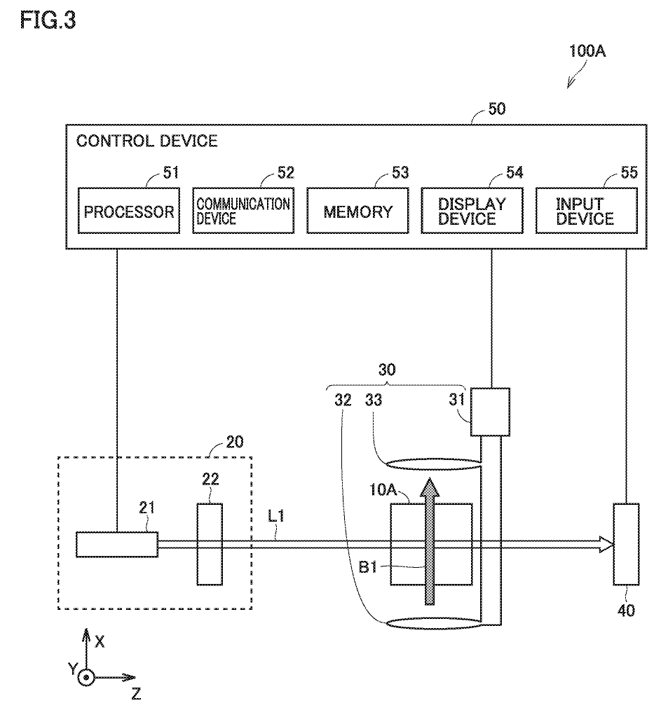

In this regard, Patent Literature 1 discloses a technique for expanding the frequency band of a measurable magnetic field by applying a static magnetic field to a cell. An OPM that applies a static magnetic field to a cell will be described below. FIG. 3 is a diagram for explaining an OPM 100A in a comparative example. Referring to FIG. 3, the OPM 100A includes a glass cell 10A in addition to the laser irradiation unit 20, the magnetic field generation unit 30, the detector 40, and the control device 50. Alkali metal atoms are enclosed in the glass cell 10A.

The OPM 100A in the comparative example can measure a periodic magnetic field according to the measurement principle described using FIG. 2. However, in the OPM 100A in the comparative example, alkali metal atoms are used as excited species used for magnetic field measurement. Therefore, it is necessary to heat the glass cell 10A in order to make the alkali metal gaseous.

The OPM 100A in the comparative example has a heater (not shown) for making the alkali metal gaseous. Since it is necessary to heat the glass cell 10 to about 200 degrees C to make the alkali metal atoms gaseous, the OPM 100A in the comparative example may reach a high temperature. Therefore, it is necessary to arrange the OPM 100A away from a measurement target (for example, a living organism). Here, it is known that the intensity of a magnetic field attenuates as the distance from a measurement target, which is a generation source of the magnetic field, increases. Although the OPM 100A in the comparative example needs to be arranged away from the measurement target for heat insulation, the measurement sensitivity may decrease due to being arranged away from the measurement target.

### OPM in Embodiment

Therefore, in the OPM 100 in Embodiment 1, helium is used as the excited species. Since helium is a gas at room temperature, there is no need for heating. Therefore, the OPM 100 can make the distance to the measurement target smaller than that of the OPM 100A in the comparative example. This can prevent the periodic magnetic field emitted from the measurement target from attenuating before being detected by the detector. According to the OPM 100 in Embodiment 1, the measurement sensitivity to the periodic magnetic field can be improved.

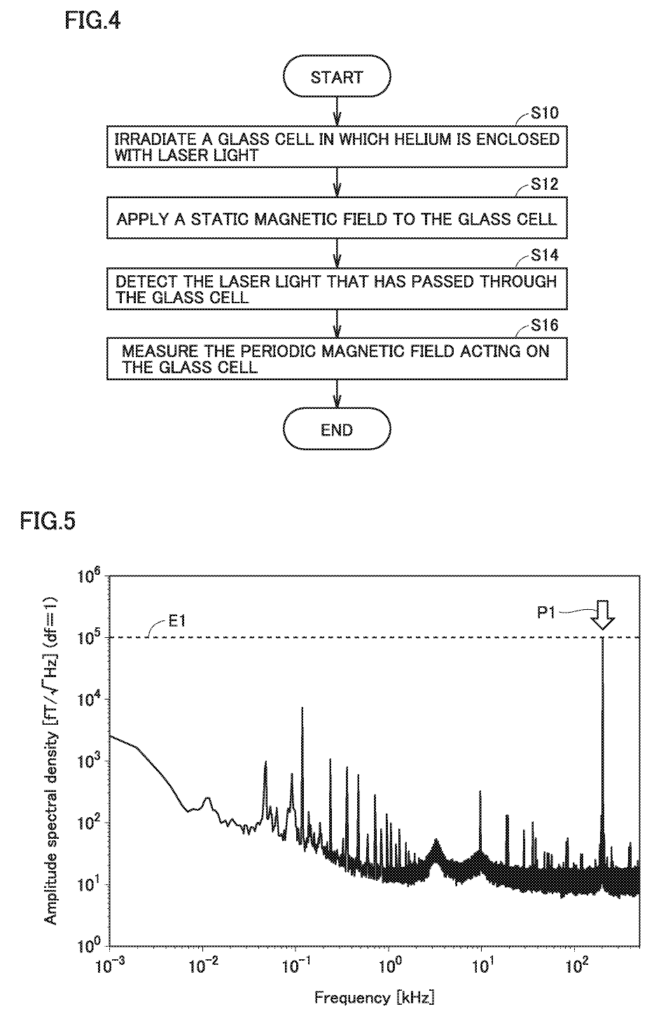

A magnetic measurement method in the present embodiment will be described. FIG. 4 is a flowchart for explaining the magnetic measurement method in Embodiment 1. The process of FIG. 4 is started, for example, in response to an instruction to measure magnetism in an application program executed in the control device 50. In one implementation example, the process of FIG. 4 is performed in a state where a magnetic field to be measured acts on the glass cell 10. The contents of the above process will be described with reference to FIG. 4.

In step S10, the control device 50 outputs a command to the laser irradiation unit 20. In response to the command, the laser irradiation unit 20 irradiates the glass cell 10 in which helium is enclosed with the laser light L1.

In step S12, the control device 50 outputs a command to the magnetic field generation unit 30. In response to the command, the magnetic field generation unit 30 applies the static magnetic field B1 to the glass cell 10.

In step S14, the detector 40 detects the laser light L1 that has passed through the glass cell 10. The detector 40 transmits the detected signal to the control device 50.

In step S16, the control device 50 measures the periodic magnetic field to be measured acting on the glass cell 10 based on the signal received from the detector 40 in step S14. Specifically, the intensity of the periodic magnetic field is derived. Thereafter, the OPM 100 ends the process of FIG. 4.

The control device 50 may display the intensity of the periodic magnetic field derived in step S16 on the display device 54.

In step S12, the intensity of the static magnetic field B1 applied to the glass cell 10 may be predetermined or may be determined by the user. For example, the user can specify the intensity of the static magnetic field B1 applied to the glass cell 10 by inputting it into the input device 55.

### Measurement Example 1

An example of measuring a periodic magnetic field using the OPM 100 in Embodiment 1 will be described below. FIG. 5 is a diagram showing a measurement result of a magnetic field by the OPM 100 in Embodiment 1.

In the experiment in Measurement Example 1, a reference magnetic field of 100 pT (effective value) and 200 kHz is applied to the glass cell 10, and measurement sensitivity to the reference magnetic field is examined. The direction of the static magnetic field B1 is adjusted to be orthogonal to the laser light L1 and the direction of polarization. Further, the direction of the static magnetic field B1 is adjusted to be orthogonal to the direction of the reference magnetic field, which is the measurement target. The intensity of the static magnetic field B1 is 7.2 μT.

FIG. 5 is a graph showing a result obtained by converting a spectral density obtained by analyzing a measurement signal into a magnetic field. In FIG. 5, the horizontal axis shows the frequency (unit: Hz) in logarithm, and the vertical axis shows the magnetic field conversion result (unit: fT/√Hz) in logarithm. Note that "√Hz" represents the square root of the frequency (Hz).

In FIG. 5, a line E1 serves as a reference for a measured magnetic field based on a result detected when a periodic magnetic field with an effective value of 100 pT was applied to the glass cell 10.

In FIG. 5, an arrow P1 indicates the intensity of a reference magnetic field with a frequency of 200 kHz measured by the OPM 100 in Embodiment 1.

In Measurement Example 1, the noise floor is 20 fT/sqrt(Hz) for a periodic magnetic field of 200 kHz. For example, in an alignment-based OPM having a glass cell in which alkali metal atoms are enclosed, which is shown as a comparative example in FIG. 3, it is reported that the noise floor for a periodic magnetic field of 10 kHz is 325 fT/sqrt(Hz) (Reference: L. M. Rushton, L. Elson, A. Meraki and K. Jensen, "Alignment-based optically pumped magnetometer using a buffer-gas cell", Phys. Rev. Appl., vol. 19, no. 6, Jun. 2023.).

The smaller the noise floor value, the more possible it is to distinguish between noise and a signal even if the signal intensity is small. Therefore, it can be evaluated that the OPM has higher sensitivity as the noise floor value is smaller.

The OPM 100 in Embodiment 1 has a smaller noise floor in the measurement of a high-frequency (for example, 10 kHz or higher) magnetic field compared to an alignment-based OPM having a glass cell in which alkali metal atoms are enclosed. That is, by using a glass cell in which helium is enclosed in the alignment-based OPM, the measurement sensitivity of a high-frequency magnetic field can be improved as compared with the case of using a glass cell in which alkali metal atoms are enclosed.

Further, the OPM 100 in Embodiment 1 can make the magnitude of the static magnetic field B1 smaller than that of the OPM 100A in the comparative example. Specifically, the OPM 100 in Embodiment 1 can make the magnitude of the static magnetic field B1 about 1/4 or less compared with the OPM 100A in the comparative example. Since this can reduce the magnitude of the current flowing through the Helmholtz coil, power consumption in measuring a periodic magnetic field can be reduced.

### Measurement Example 2

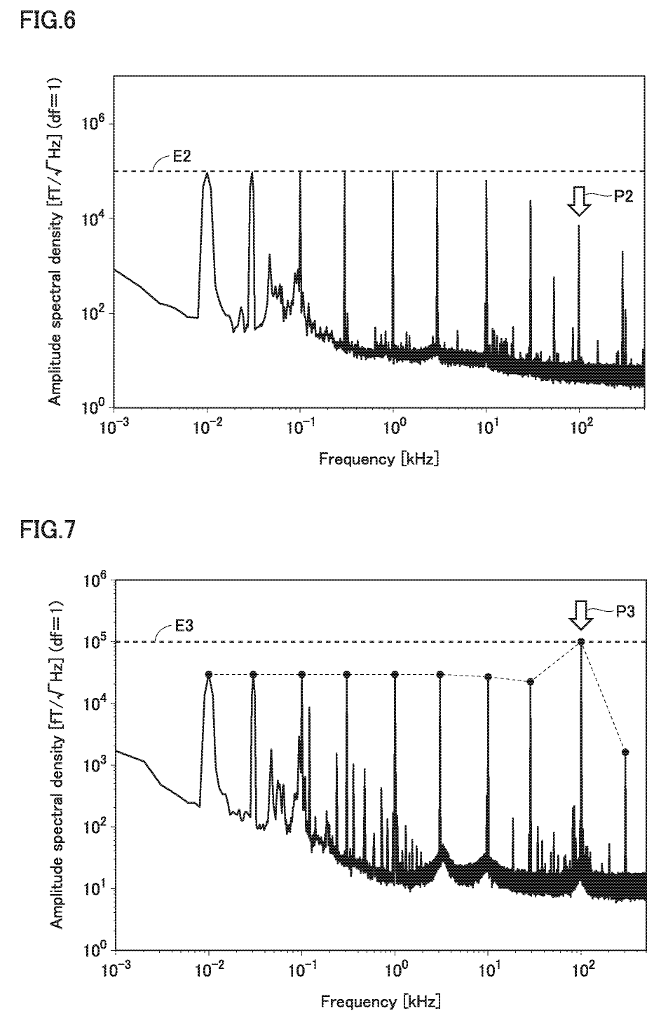

Another example of measuring a periodic magnetic field using the OPM 100 in Embodiment 1 will be described below with reference to FIGS. 6 and 7. FIGS. 6 and 7 are diagrams showing magnetic field measurement results by the OPM 100 in Embodiment 1. FIG. 6 shows a measurement result obtained when no static magnetic field B1 was generated, and FIG. 7 shows a measurement result obtained in a state where the static magnetic field B1 was generated by the magnetic field generation unit 30.

In the experiment in Measurement Example 2, a periodic magnetic field in which a plurality of frequency components are arranged at regular intervals is applied to the glass cell 10 as a reference magnetic field, and the sensitivity to the reference magnetic field is examined. Specifically, the reference magnetic field includes magnetic field components having frequencies of 10 Hz, 30 Hz, 100 Hz, ... 300 kHz, and the intensity of each component is 100 pT (effective value). The static magnetic field B1 was made orthogonal to the direction of the laser light L1 and its polarization. Further, the reference magnetic field, which is the measurement target, and the static magnetic field B1 were made orthogonal. The intensity of the static magnetic field B1 is 3.6 μT.

6 and 7 are graphs showing results obtained by converting the spectral density analyzed from the measurement signal into a magnetic field, similar to FIG. 5. In FIGS. 6 and 7, the horizontal axis shows the frequency (unit: Hz) in logarithm, and the vertical axis shows the magnetic field conversion result (unit: fT/√Hz) in logarithm. Note that "√Hz" represents the square root of the frequency (Hz).

Similarly to the line E1 in FIG. 5, each of the line E2 and line E3 in FIGS. 6 and 7 shows a reference value detected when a periodic magnetic field with an effective value of 100 pT was applied to the glass cell 10.

FIG. 6 shows a measurement result obtained when no static magnetic field B1 was generated. In this case, as the frequency of the reference magnetic field increases, the measured value of each frequency component decreases. That is, when the static magnetic field B1 is not generated, the detection sensitivity to a periodic magnetic field having a frequency of 100 kHz or higher decreases. Note that the case where the static magnetic field B1 is not generated can also be rephrased as a measurement result in the case of using an OPM not provided with the magnetic field generation unit 30.

FIG. 7 shows a measurement result obtained in a state where the static magnetic field B1 was generated by the magnetic field generation unit 30. In this case, the peak intensity of a periodic magnetic field having a frequency of 100 kHz is about the same as the magnitude of the line E3. Therefore, by generating the static magnetic field B1 by the magnetic field generation unit 30, it is possible to detect a periodic magnetic field having a frequency of 100 kHz with high sensitivity. Further, for example, in FIG. 7, the peak intensity of a periodic magnetic field having a frequency of 100 kHz is larger than the peak intensity of a periodic magnetic field having a frequency of 30 kHz and the peak intensity of a periodic magnetic field having a frequency of 300 kHz. Therefore, by applying the static magnetic field B1 of 3.6 μT to the glass cell 10, the detection sensitivity to a periodic magnetic field having a frequency of 100 kHz can be selectively improved.

According to the OPM 100 in Embodiment 1, it is possible to improve measurement sensitivity to a periodic magnetic field in an OPM. Specifically, by using helium atoms instead of alkali metal atoms as excited species, there is no need for heating, so the OPM can be brought closer to the measurement target. This can prevent a weak high-frequency magnetic field emitted from the measurement target from attenuating.

### Embodiment 2

In Embodiment 1, the OPM 100 having a configuration called an alignment-based OPM using a single laser beam has been described, but it is not limited to this configuration. Specifically, the OPM may have a configuration in which a pump laser beam and a probe laser beam are orthogonal to each other. Note that an OPM having a configuration in which a pump laser beam and a probe laser beam are orthogonal to each other is sometimes called a pump-probe type OPM and a biaxial orthogonal type OPM.

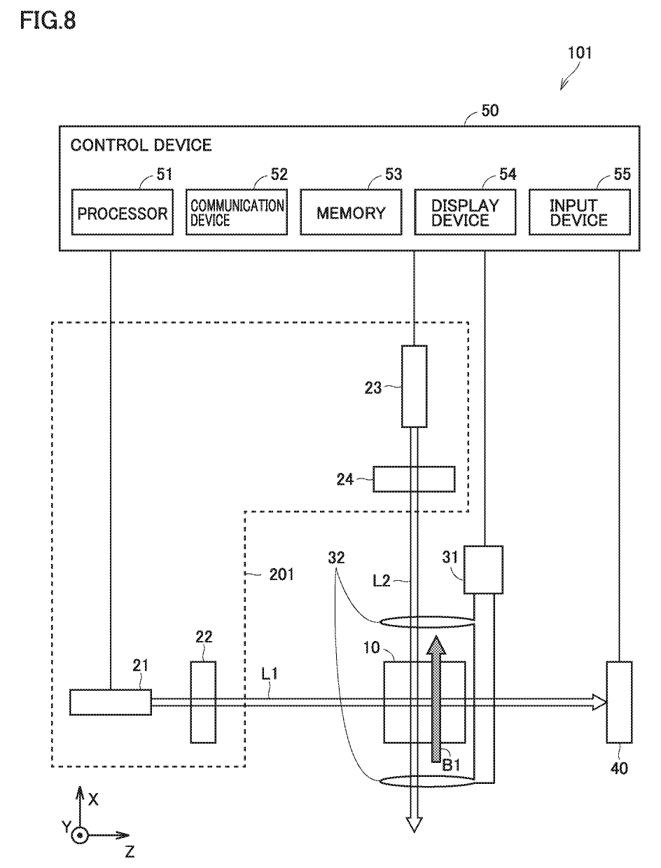

FIG. 8 is a diagram schematically showing a configuration of an OPM 101 in Embodiment 2. The OPM 101 includes a laser irradiation unit 201 in addition to the glass cell 10, the magnetic field generation unit 30, the detector 40, and the control device 50.

The laser irradiation unit 201 includes a second light source 23 and a second polarizing element 24 in addition to the first light source 21 and the first polarizing element 22. Laser light L2 emitted by the second light source 23 is irradiated to the glass cell 10 after passing through the second polarizing element 24. The second polarizing element 24 includes an element that converts input light into a linearly polarized wave. Therefore, the laser light L2 that passes through the second polarizing element 24 and is irradiated to the glass cell 10 is a linearly polarized wave. The second polarizing element 24 is, for example, a 1/2 wavelength plate or a 1/4 wavelength plate.

The laser light L2 functions as pump light for exciting helium atoms in the glass cell 10. The wavelength of the laser light L2, which is pump light, is, for example, 1083 nm. Helium atoms enclosed in the glass cell 10 form a predetermined spin polarization by absorbing the laser light L2, which is pump light.

In Embodiment 2, the laser light L1 functions as probe light for examining the state of spin polarization of helium atoms in the glass cell 10. When the laser light L1 passes through the glass cell 10, the polarization changes according to the state of spin polarization of helium atoms in the glass cell 10. By detecting the change in polarization by the detector 40, the intensity of the magnetic field to be measured can be measured.

The laser light L1 is irradiated from the first light source so as to intersect the laser light L2. More preferably, the laser light L1 is irradiated from the first light source so as to be orthogonal to the laser light L2. Further, the magnetic field generation unit 30 applies the static magnetic field B1 to the glass cell 10 so that the direction of the static magnetic field B1 intersects the laser light L1.

According to the OPM 101 in Embodiment 2, wavelengths of the laser light L2, which is pump light, and the laser light L1, which is probe light, can be changed. Thereby, the laser light L2 can be set to a wavelength suitable for exciting excited species, and the laser light L1 can be set to a wavelength suitable for detecting changes of polarized spins. Thus, by using different wavelengths, measurement sensitivity can be improved.

Further, in Embodiment 2, the second polarizing element 24 may include an element that converts input light into a circularly polarized wave. In this case, the laser light L2 passing through the second polarizing element 24 and irradiated to the glass cell 10 becomes a circularly polarized wave.

By making the laser light L2 a circularly polarized wave, it is possible to selectively perform optical pumping of excited species into a specific spin state (Zeeman level).

Note that while the OPM 101 in Embodiment 2 is provided with two or more laser light sources, the OPM 100 in Embodiment 1 is provided with one laser light source. Therefore, according to the OPM 100 in Embodiment 1, manufacturing cost can be reduced compared with the OPM 101 in Embodiment 2. Further, since the number of light sources is small, the OPM 100 in Embodiment 1 can be downsized and space-saved compared with the OPM 101 in Embodiment 2.

### Aspects

Those skilled in the art will understand that the above-described embodiments and modification examples thereof are specific examples of the following aspects.

(Item 1) An optically pumped magnetometer (OPM) according to the present disclosure may include a cell in which helium is enclosed, a laser irradiation unit that irradiates the cell with first laser light, a magnetic field generation unit that applies a static magnetic field to the cell in a direction intersecting the first laser light, a detector that detects the first laser light that has passed through the cell, and a control device that controls the magnetic field generation unit and measures a periodic magnetic field acting on the cell based on a detection result of the detector.

According to the optically pumped magnetometer described in Item 1, measurement sensitivity to a periodic magnetic field can be improved.

(Item 2) In the optically pumped magnetometer described in Item 1, the control device may control an intensity of the static magnetic field.

According to the optically pumped magnetometer described in Item 2, the intensity of the static magnetic field can be adjusted according to the frequency of the periodic magnetic field to be measured. Thereby, measurement sensitivity to a periodic magnetic field having a specific frequency can be selectively improved.

(Item 3) In the optically pumped magnetometer described in Item 1 or 2, the laser irradiation unit includes a first light source that emits first laser light and a first polarizing element that converts the first laser light into a linearly polarized wave, and the first laser light may be laser light in a predetermined wavelength range that can be used as pump light for exciting the helium and probe light for detecting spin polarization of the helium.

According to the optically pumped magnetometer described in Item 3, manufacturing cost of the OPM can be reduced. Further, the OPM can be downsized and space-saved.

(Item 4) The optically pumped magnetometer described in any one of Items 1 to 3 may be an alignment-based optically pumped magnetometer.

According to the optically pumped magnetometer described in Item 4, measurement sensitivity to a periodic magnetic field of an alignment-based optically pumped magnetometer can be improved.

(Item 5) In the optically pumped magnetometer described in Item 1 or 2, the laser irradiation unit may include a first light source that emits first laser light, a second light source that emits second laser light in a direction intersecting the first laser light, a first polarizing element that converts the first laser light into a linearly polarized wave, and a second polarizing element that converts the second laser light into a circularly polarized wave.

(Item 6) In the optically pumped magnetometer described in Item 1 or 2, the laser irradiation unit may include a first light source that emits first laser light, a second light source that emits second laser light in a direction intersecting the first laser light, a first polarizing element that converts the first laser light into a linearly polarized wave, and a second polarizing element that converts the second laser light into a linearly polarized wave.

According to the optically pumped magnetometer described in Item 6, wavelengths of pump light and probe light can be changed. Thereby, the pump light can be set to a wavelength suitable for exciting excited species, and the probe light can be set to a wavelength suitable for detecting changes of polarized spins. Thus, by using different wavelengths, measurement sensitivity to a periodic magnetic field in an OPM can be improved.

(Item 7) In the optically pumped magnetometer described in any one of Items 1 to 6, the magnetic field generation unit may include a Helmholtz coil.

According to the optically pumped magnetometer described in Item 7, a static magnetic field is applied to the glass cell by the Helmholtz coil. By adjusting the magnitude of the current flowing through the Helmholtz coil, measurement sensitivity to a high-frequency magnetic field having a specific frequency can be selectively improved.

(Item 8) A magnetic measurement method according to the present disclosure may include a step of irradiating a cell in which helium is enclosed with laser light, a step of applying a static magnetic field to the cell in a direction intersecting the laser light, a step of detecting the laser light that has passed through the cell, and a step of measuring a periodic magnetic field acting on the cell based on a detection result in the step of detecting.

According to the magnetic measurement method described in Item 8, measurement sensitivity to a periodic magnetic field can be improved.

The embodiments disclosed this time should be considered as illustrative and not restrictive in all respects. The scope of the present disclosure is indicated not by the above description of the embodiments but by the scope of claims, and is intended to include all modifications within the meaning and scope equivalent to the scope of claims. Further, each technique in the embodiments is intended to be implemented alone or in combination with other techniques in the embodiments as much as possible as needed.

### REFERENCE SIGNS LIST

10, 10A glass cell, 20, 201 laser irradiation unit, 21 first light source, 22 first polarizing element, 23 second light source, 24 second polarizing element, 30 magnetic field generation unit, 31 power supply device, 32, 33 coil, 40 detector, 50 control device, 51 processor, 52 communication device, 53 memory, 54 display device, 55 input device, 100, 100A, 101 optically pumped magnetometer (OPM).

1. An optically pumped magnetometer comprising:
a cell in which helium is enclosed;
a laser irradiation unit that irradiates the cell with first laser light;
a magnetic field generation unit that applies a static magnetic field to the cell in a direction intersecting the first laser light;
a detector that detects the first laser light that has passed through the cell; and
a control device that controls the magnetic field generation unit and measures a periodic magnetic field acting on the cell based on a detection result of the detector.

2. The optically pumped magnetometer according to claim 1, wherein the control device controls an intensity of the static magnetic field.

3. The optically pumped magnetometer according to claim 1, wherein the laser irradiation unit includes a first light source that emits the first laser light and a first polarizing element that converts the first laser light into a linearly polarized wave, and
the first laser light is laser light in a predetermined wavelength range that can be used as pump light for exciting the helium and probe light for detecting spin polarization of the helium.

4. The optically pumped magnetometer according to claim 1, which is an alignment-based optically pumped magnetometer.

5. The optically pumped magnetometer according to claim 1, wherein the laser irradiation unit includes:
a first light source that emits the first laser light;
a second light source that emits second laser light in a direction intersecting the first laser light;
a first polarizing element that converts the first laser light into a linearly polarized wave; and
a second polarizing element that converts the second laser light into a circularly polarized wave.

6. The optically pumped magnetometer according to claim 1, wherein the laser irradiation unit includes:
a first light source that emits the first laser light;
a second light source that emits second laser light in a direction intersecting the first laser light;
a first polarizing element that converts the first laser light into a linearly polarized wave; and
a second polarizing element that converts the second laser light into a linearly polarized wave.

7. The optically pumped magnetometer according to claim 1, wherein the magnetic field generation unit includes a Helmholtz coil.

8. A magnetic measurement method comprising:
a step of irradiating a cell in which helium is enclosed with laser light;
a step of applying a static magnetic field to the cell in a direction intersecting the laser light;
a step of detecting the laser light that has passed through the cell; and
a step of measuring a periodic magnetic field acting on the cell based on a detection result in the step of detecting.
